(19) United States
(12) Patent Application Publication
(10) Pub. No.: US 2023/0327803 A1
(43) Pub. Date: Oct. 12, 2023

(54) Communication FEC Optimization for Virtualized Platforms

(71) Applicant: Parallel Wireless, Inc., Nashua, NH (US)

(72) Inventors: Ofir Ben Ari Katzav, Kadima-Zoran (IL); Roy Nahum, Tzur Itzhak (IL); Joe Holland, Bristol, NH (US); Koby Shimonovich, Harish (IL); Eli Genkin, Petah Tikva (IL)

(21) Appl. No.: 18/190,967

(22) Filed: Mar. 27, 2023

Related U.S. Application Data
(60) Provisional application No. 63/323,572, filed on Mar. 25, 2022.

(51) Int. Cl. H04L 1/00

(52) U.S. Cl. CPC H04L 1/0061

(57) ABSTRACT

In one embodiment, a method for providing communication Forward Error Correction (FEC) optimization for virtualized platforms, comprising: calculating a cut off time used to terminate total FEC processing duration; processing code blocks received in a subframe in an order defined by a sorting stage; and wherein processing code blocks comprises: checking if a current time has exceeded the cut off time cut off value; when the current time has exceeded the cut off time value, then setting a Cyclic Redundancy Code (CRC) FAIL and moving onto a next code block without decoding; when the current time has not exceeded the cut off time value, then running a single iteration of decoding and checking a code block CRC; when the code block CRC is PASS then decoding is successful and moving onto a next code block; when the code block CRC is FAIL then checking if a maximum number of FEC iterations has been reached; when maximum number of FEC iterations has not been reached repeating the steps of calculating and processing code blocks; and when maximum number of FEC iterations has been reached then moving onto the next code block.

### CROSS-REFERENCE TO RELATED APPLICATIONS

The present application claims priority under 35 U.S.C. § 119(e) to U.S. Provisional Patent Application No. 63/323,572, having the same title as the present application and hereby incorporated by reference for all purposes. The present application also hereby incorporates by reference U.S. Pat. App. Pub. Nos. US20110044285, US20140241316; WO Pat. App. Pub. No. WO2013145592A1; EP Pat. App. Pub. No. EP2773151A1; U.S. Pat. No. 8,879,416, “Heterogeneous Mesh Network and Multi-RAT Node Used Therein,” filed May 8, 2013; U.S. Pat. No. 8,867,418, “Methods of Incorporating an Ad Hoc Cellular Network Into a Fixed Cellular Network,” filed Feb. 18, 2014; U.S. Pat App. No. 14/777,246, “Methods of Enabling Base Station Functionality in a User Equipment,” filed Sep. 15, 2016; U.S. Pat. App. No. 14/289,821, “Method of Connecting Security Gateway to Mesh Network,” filed May 29, 2014; U.S. Pat. App. No. 14/642,544, “Federated X2 Gateway,” filed Mar. 9, 2015; U.S. Pat. App. No. 14/711,293, “Multi-Egress Backhaul,” filed May 13, 2015; U.S. Pat. App. No. 62/375,341, “S2 Proxy for Multi-Architecture Virtualization,” filed Aug. 15, 2016; U.S. Pat. App. No. 15/132,229, “MaxMesh: Mesh Backhaul Routing,” filed Apr. 18, 2016, each in its entirety for all purposes, having attorney docket numbers PWS-71700US01, 71710US01, 71717US01, 71721US01, 71756US01, 71762US01, 71819US00, and 71820US01, respectively. This application also hereby incorporates by reference in their entirety each of the following U.S. Pat. applications or Pat. App. Publications: US20150098387A1 (PWS-71731US01); US20170055186A1 (PWS-71815US01); US20170273134A1 (PWS-71850US01); US20170272330A1 (PWS-71850US02); and 15/713,584 (PWS-71850US03). This application also hereby incorporates by reference in their entirety U.S. Pat. Application No. 16/424,479, “5G Interoperability Architecture,” filed May 28, 2019; and U.S. Provisional Pat. Application No. 62/804,209, “5G Native Architecture,” filed Feb. 11, 2019, and U.S. Pat. App. No. 18/174580, titled “O-RAN Compatible Deployment Architecture” and filed Feb. 24, 2023.

### BACKGROUND

In wireless communication systems (as well as for wired ones) there is a vast use in FEC blocks to increase communication reliability. Common approaches are convolution codes, turbo codes and LDPC which are widely used for cellular networks as well. Although those are considered as common practice and usually defined by the standards, it’s considered relatively heavy operation in terms of compute power during implementation. The traditional approach is to build such encoders and decoders in hardware (e.g. FPGA/ASIC).

### SUMMARY

The disclosed invention defines a novel approach to dynamically manage FEC processing functionality within a resource constrained system. We propose several approaches to handle and relax the FEC processing demand as well as dynamic compute resources allocation for the FEC entity in virtualized RAN architecture. With part or all of the proposed items, optimized performance and compute resources achieved and retained over time.

In one embodiment a method for providing communication Forward Error Correction (FEC) optimization for virtualized platforms includes calculating a cut off time used to terminate total FEC processing duration; processing code blocks received in a subframe in an order defined by a sorting stage; and wherein processing code blocks comprises: checking if a current time has exceeded the cut off time cut off value; when the current time has exceeded the cut off time value, then setting a Cyclic Redundancy Code (CRC) FAIL and moving onto a next code block without decoding; when the current time has not exceeded the cut off time value, then running a single iteration of decoding and checking a code block CRC; when the code block CRC is PASS then decoding is successful and moving onto a next code block; when the code block CRC is FAIL then checking if a maximum number of FEC iterations has been reached; when maximum number of FEC iterations has not been reached repeating the steps of calculating and processing code blocks; and when maximum number of FEC iterations has been reached then moving onto the next code block.

### BRIEF DESCRIPTION OF THE DRAWINGS

FIG. 1 is a schematic diagram of radio functional splits showing split 7.2X RU as well as other splits, in accordance with some embodiments.

FIG. 2 is a schematic flow diagram showing operation of a FEC processing flow, in accordance with some embodiments.

FIG. 3 is a schematic diagram of an Open RAN 4G/5G deployment architecture, in accordance with some embodiments.

FIG. 4 is a schematic diagram of a multi-RAT core network architecture, in accordance with some embodiments.

FIG. 5 is a schematic diagram of a multi-RAT RAN deployment architecture, in accordance with some embodiments.

FIG. 6 is an enhanced eNodeB for performing the methods described herein, in accordance with some embodiments.

### DETAILED DESCRIPTION

In the virtualized implementation architecture, the PHY layer can be implemented on a general-purpose CPU which doesn’t contain the facilities for such compute intense operations. Here again, a common approach will be to attach to such architecture HW acceleration components to offload the general-purpose CPU. In more advanced approaches, it’s considered to have the full encoder and decoder implemented on the CPU and avoid HW acceleration attachments. Such approach is more suitable for cloud-based RAN architecture for example.

Since such a compute intense operation is loaded on a general-purpose CPU, it requires greater amount of system resources which increases the solution price. Vector processing accelerators embedded in such CPUs can be used to dramatically relax the required compute power. In addition to such optimization, the system design shall also consider the resources allocation and management to balance between the product cost and performance. Namely, system designed for worse case scenarios (or close to that) will require allocation of more CPU power compared to ones designed for low reliability. It’s important to note, that each decoding operation consists with multiple decoder iteration and in some cases (e.g. 3G, LTE, 5G) runs on multiple code words on the same time slot.

In cellular networks, reliability must be maintained in parallel of solution cost reduction. In terms for decoder, reliability is depicted by various of parameters (e.g. code rate and modulation) and specifically by the number of iterations (turbo codes and LDPC for example) used in the decoder where each iteration improves the decoding probability in some measure. In a resource limited solution (such one that aim to balance cost and performance), the system shall allow specific distribution of the decoder iterations. The later defines the compute resources distribution for a given time slot to allow some percentage of high number of iterations, some percentage for average number of iteration and rest for low number of iteration (granularity can be defined in various ways). Forcing such limitations in the system will make it work properly for an average case but doesn’t properly handle escalated cases (e.g. worse average channel conditions which requires more decoding iterations) in such degraded cases, the system loses robustness and may cause severe timing issues.

### Radio Unit Functional Splits

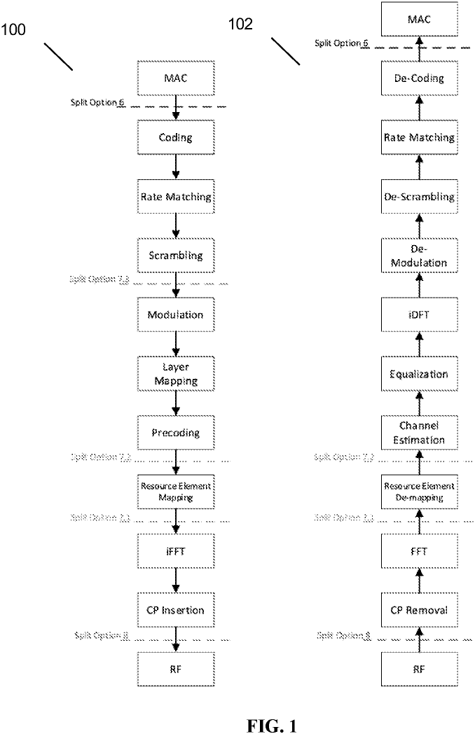

FIG. 1 is a schematic diagram of radio functional splits showing split 7.2X RU as well as other splits. The use of these functional splits is encouraged by ORAN.

5G New Radio (NR) was designed to allow for disaggregating the baseband unit (BBU) by breaking off functions beyond the Radio Unit (RU) into Distributed Units (DUs) and Centralized Units (CUs), which is called a functional split architecture. This concept has been extended to 4G as well.

RU: This is the radio hardware unit that coverts radio signals sent to and from the antenna into a digital signal for transmission over packet networks. It handles the digital front end (DFE) and the lower PHY layer, as well as the digital beamforming functionality. 5G RU designs are supposed to be inherently intelligent, but the key considerations of RU design are size, weight, and power consumption. Deployed on site.

DU: The distributed unit software that is deployed on site on a COTS server. DU software is normally deployed close to the RU on site and it runs the RLC, MAC, and parts of the PHY layer. This logical node includes a subset of the eNodeB (eNB)/gNodeB (gNB) functions, depending on the functional split option, and its operation is controlled by the CU.

CU: The centralized unit software that runs the Radio Resource Control (RRC) and Packet Data Convergence Protocol (PDCP) layers. The gNB consists of a CU and one DU connected to the CU via Fs-C and Fs-U interfaces for CP and UP respectively. A CU with multiple DUs will support multiple gNBs. The split architecture lets a 5G network utilize different distributions of protocol stacks between CU and DUs depending on midhaul availability and network design. It is a logical node that includes the gNB functions like transfer of user data, mobility control, RAN sharing (MORAN), positioning, session management etc., except for functions that are allocated exclusively to the DU. The CU controls the operation of several DUs over the midhaul interface. CU software can be co-located with DU software on the same server on site.

When the RAN functional split architecture (FIG. 1) is fully virtualized, CU and DU functions runs as virtual software functions on standard commercial off-the-shelf (COTS) hardware and be deployed in any RAN tiered datacenter, limited by bandwidth and latency constraints.

Option 7.2 (shown) is the functional split chosen by the O-RAN Alliance for 4G and 5G. It is a low-level split for ultra-reliable low-latency communication (URLLC) and near-edge deployment. RU and DU are connected by the eCPRI interface with a latency of ~100 microseconds. In O-RAN terminology, RU is denoted as O-RU and DU is denoted as O-DU. Further information is available in US20200128414A1, hereby incorporated by reference in its entirety.

### Iterative FEC and CPU Processing Time

The FEC processing time is usually designed to allow proper processing under some limitations. A simple one is termination based on iterations count (e.g. in Turbo codes and LDPC). The tuning of the maximal number of iterations required to a low probability of indicating bad CRC although in case of infinite amount of FEC iterations can result with good CRC. Such tuning is commonly done based on air channel outage probability. Defining the optimum value of maximum iterations in an FEC scheme is a trade-off between the decoder performance and processing time.

An important feature of many FEC algorithms is the concept of early termination. In an early termination scheme the code block is checked after each FEC iteration to determine if it has been decoded correctly. This check can be performed in a variety of ways, e.g. through a code block CRC as in 4G Turbo code, or a syndrome check in LDPC. If it is determined that the code block has been decoded correctly then the FEC processing will terminate. If the decode is determined incorrect then another FEC iteration will be performed, and the process repeats. This will continue until the code block is correctly decoded, or the maximum number of iterations is reached.

This leads to two observations on FEC processing time in iterative decoding systems -

The theoretical worse case processing time for the FEC is therefore determined by the value of maximum iterations. e.g. no code blocks terminate early.

The real-world processing time for FEC will be significantly lower than the theoretical maximum. e.g. there will be a distribution of FEC iterations between 1 and maximum.

In resource constrained systems the processing time of the FEC must be completed within a fixed time budget. A good example comes from 4G/5G where multiple users’ data shall be decoded by the FEC block at the same sub-frame. The FEC processing time the subframe is highly variable due to changing channel conditions and link adaptation decisions.

If the system is architected to guarantee enough CPU resource to process all code blocks up to the fixed maximum number of iterations, then it is not resource constrained and the time budget can never be exceeded. The system is high cost, but robust by design.

If a system is architected only to provide enough CPU resource for the “real-world” average case, it is possible that certain scenarios may push FEC processing to exceed the timing budget. The system will have much lower cost but is no longer robust.

The proposal in this document defines novel approach to dynamically manage such cases to maximize FEC performance within the allocated CPU resources whilst guaranteeing robustness.

The proposed invention is a method of dynamically controlling FEC processing on a resource constrained system in order to maximize wireless performance, while guaranteeing that timing budgets are not exceeded.

The example application described is 4G communications processing, but the mechanism itself is generic to any system using iterative decoding FEC (e.g. 5G) with fixed processing budgets.

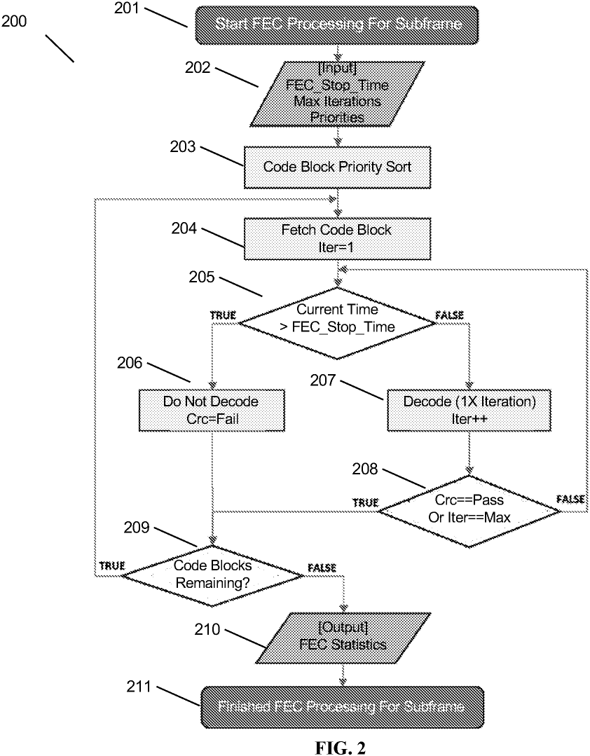

FIG. 2 is a schematic flow diagram showing operation of a FEC processing flow, in accordance with some embodiments. At step 201, FEC processing begins for a specific subframe. At step 202, three input parameters are received: an FEC stop time, a maximum number of iterations, and a priority list. At step 203, a code block priority sort is performed to sort the code blocks. At step 204, the next code block in the sorted list of code blocks is fetched. At step 205, a test is performed to evaluate whether the current time is greater than the FEC stop time, in which case step 206, do not decode, is performed if true, or else if not true decoding occurs at step 207. Step 206 also results in a variable, CRC, being set to a FAIL value. At step 207, if decoding succeeds CRC is set to Pass. At step 208, if either the decoding has succeeded and CRC has previously been set to Pass, or if the number of elapsed iterations has reached the maximum number of iterations, control passes to 209, or if neither condition is true, additional iteration on FEC decode is performed, thereby enabling an FEC decode loop. At step 209, after each block is decoded, if there are additional blocks remaining, control is passed to step 204 and a new code block is fetched. Else, if there are no additional code blocks remaining, processing passes to step 210. At step 210, FEC statistics are output. At step 211, FEC processing for the subframe is ended.

### FEC Termination Based on Timing Budget

A foundation of the invention is an extension to the FEC early termination concept to add termination based on timing budget. At a high level this is characterized by the calculation of a point in time after which FEC processing will stop attempting to decode and all remaining code blocks are considered undecodable. The following text describes such a mechanism working using the example of a communications system where all code blocks must be processed by the FEC within the same time frame.

At the start of each time frame period a cut off time (FEC_STOP_TIME) is calculated that will be used to terminate total FEC processing duration allowed for the time frame (with or without margin).

Before any code blocks are processed, they are sorted into priority order.

The FEC then begins processing the code blocks received in the subframe in the order defined by the sorting stage.

For each code block - Check if the current time has exceeded the FEC_STOP_TIME cut off value. If YES set the CRC to FAIL and move onto the next code block without decoding. If NO run 1x iteration of decoding and check the code block CRC. If the CRC is PASS then decode is successful and move onto next code block. If the CRC is FAIL check if maximum number of FEC iterations has been reached. If MAX number of FEC iterations has not been reached got to step (1). If MAX number of FEC iterations has been reached move onto next code block.

The above sequence is followed until all code blocks in the time frame have been processed.

With this mechanism in place the time budget for FEC is guaranteed not to be exceeded in any scenario.

When sufficient CPU resources are available, the FEC performance is indistinguishable from non-resource constrained system. When CPU resources are constrained and insufficient, increase in BLER will be observed, with code blocks processed later in time more likely to be affected.

Due to the fact the mechanism is “reactive” rather than “predictive” it does not make assumptions about worse case processing times and therefore will always perform “best effort” based on the setting of maximum iterations and available CPU resources. Given proper sorting algorithms (described below) system performance degradation can be minimized.

### Code Block Priority Sort

As an extension to the above, a sorting mechanism can be added to control which code blocks will gain priority in the resource limited system running the FEC. We propose several sorting mechanisms:

### Range Biased Sorting Method

in systems with emphasis on service range, the sorter shall prioritize code blocks to be processed by the FEC such that the code blocks coming from high range users will be handled first.

Code blocks sorter identifies users in high range based on one or more of the following:
Physical location information
Relative distance information
Link attenuation measurement/estimation
Power control loop indication - under the assumption that higher power stands with high correlation to higher range in a system that strive to optimize user’s battery consumption.

Link adaptation indication - under the assumption that lower modulation and code rate will be used for users with higher distance from the serving entity.

### TPT Biased Sorting Method

In systems with emphasis on TPT, the sorter will prioritize code blocks which carries the most information bits to be handled by the FEC block first. Since the modulation, code rate, block size and similar parameters are well known in the system and required for proper decoding, those can be leveraged in the sorter to set the priorities of the code block such that maximal TPT will be achieved.

### Highest Decoding Probability Sorting Method

In this method, the sorter will prioritize the code blocks based on their likelihood to be decoded fast and reliably.

The sorter decision mechanism considers one or more of the following:

SNR or SINR of the received signal combined with a prior data for the decoding probability - e.g. SINR is higher than a margin compared to the required SINR for successful decoding of a given code block characteristics.

Interference amount on the received signal.

Soft decision metric such as LLRs (Log-Likelihood Ratio) significance

### Hybrid Sorter

Any combination of the mentioned sorter approaches aimed to strike new balance between the approaches.

Hybrid sorter can be defined by one or more of the following:

Weighted cost function generation to create cross-methods priority.

Proportional fairness between range and spectral efficiency - static or dynamic selection of the amount of high range user’s code blocks to be allocated at the top of the priority list and then next slots will be sorted by the sorter biased toward spectral efficiency and/or vice versa.

### Randomizer (no Priority)

Order is randomized such that all users have equal chance of their code blocks being “low” priority and therefore being affected by lack of CPU resource.

The increase on BLER due to CPU overload will therefore be seen equally across all users and will appear as a decrease in receiver sensitivity.

### History Aware Sorter:

Any method above can be extended to include history knowledge such that users who granted lower priority in previous time frames will be biased in the sorter for the next time frame.

History aware sorter can take advantage of one or more of the following:

Previous actions of the FEC operation such as codewords which were declared as CRC failure due to not being processed because of breaching the FEC time budget.

Historical statistics on CRC failure per user can be utilized to bias weaker links (with higher CRC failure statistics). This approach can be implemented with short- or long-term averaging where a special case is to consider the last code word only.

### Power Control and Link Adaptation Relationship

In a common communication system, the characteristics of the FEC can be dominated by the decisions of the power control and link adaptation mechanisms. We propose a new feedback approach from the FEC to those mechanisms to allow control of the FEC performance over time.

Namely, we propose gathering of FEC statistics per user or per serving entity including FEC processing time, number code blocks affected by CPU limitations, and distribution of iterations observed.

These statistics can be used to adjust the power control and link adaptation such that the FEC block will provide more / less processing gain per given processing time budget.

The above can be achieved by one or more of the following:

Increase/decrease power based on the user’s headroom and the FEC statistics (early termination + max iteration decision). Namely, power control loop can adjust the received SNR per user by increase/decrease of the transmit power - this is somewhat equivalent (not linearly) to FEC gain. Specifically, the power control loop can increase user’s transmit power to improve receive SNR, which shall be translated to decreased FEC iterations and hence saving in FEC compute duration.

Increase/decrease MCS in similar approach as above.

FEC gain per iteration can be quantified either empirically or dynamically in terms of dBs (or equivalent). Reduced FEC iterations can be compensated by power control loop or link adaptation. Similar approach can also consider interference level or in general SINR.

More generally, the power control and link adaptation can monitor FEC statistics and decide to be more/less aggressive in either power and/or MCS selection thus, changing robustness of the link. In turn, this affects the required processing for the FEC block and hence the duration of it.

### Dynamic Adaption of FEC Compute Resources

As an extension to the above, we propose a method to adjust the FEC processing capabilities dynamically based on FEC performance characteristics. The system can hold FEC monitoring ability to track mainly the amount of FEC iterations used per case and the amount of code words declared as CRC failure due to breaching FEC time budget along with optional side information on link quality, power control loop and link adaptation. Based on the monitored data, in a flexible system (e.g. vRAN), the system can increase or decrease the amount of compute power allocated to the FEC processing. The main benefit of this approach is well tuned and flexible system design when the FEC processing is done for multiple carriers within the same entity or multiple entities running on the same hardware.

Adjustments are considered according to one or more of the following:

Maximal iteration per code word adjusted globally to the system - limiting maximal iterations allowed for all code words will evenly reduce the maximal decoding time for all cases and thus allow higher chances to process the last code words in the buffer with potential small degradation in performance.

Maximal iteration adjustment per user/code word - employs looser or tighter time constrain per user / codeword. This approach can be used to provide different prioritization between users / codewords.

Maximal iteration per codeword can be adjusted based on trained algorithm (e.g. machine learned algorithm based on historical data). Namely, one can set the maximal iteration limitation per each codeword based on the received signal matrices (e.g. SNR/SINR/CQI/interference level/etc.) such that the defined max iteration count per code block will maximize overall decoding probability of all blocks in time frame. With such approach, a global pool of iterations can be managed for all codewords per time frame. In turn, the system management entity can easily track and monitor the iteration pool for the complete decoding processes, increase/decrease than as per need.

FEC processing power allocation per channel type / QCI / bearer / traffic profile -allowing higher FEC processing capabilities for codewords with higher importance (e.g. emergency services / low latency services / etc.) with compromising less important profiles when system compute resources unable to complete all codewords processing within the time frame.

When the FEC processing is running in the CU or DU where there is some flexibility for compute resources allocation for different tasks, the FEC can be allocated with more/less compute resources based on its statistics. Namely, when identifying that the FEC processing is breaching time limitations with some statistics, the compute resources manager can allocate more compute power to the FEC block and vice versa. The main benefit of this approach is a well-balanced system that optimizes the sharing of the compute resources in a platform with multiple applications running on it.

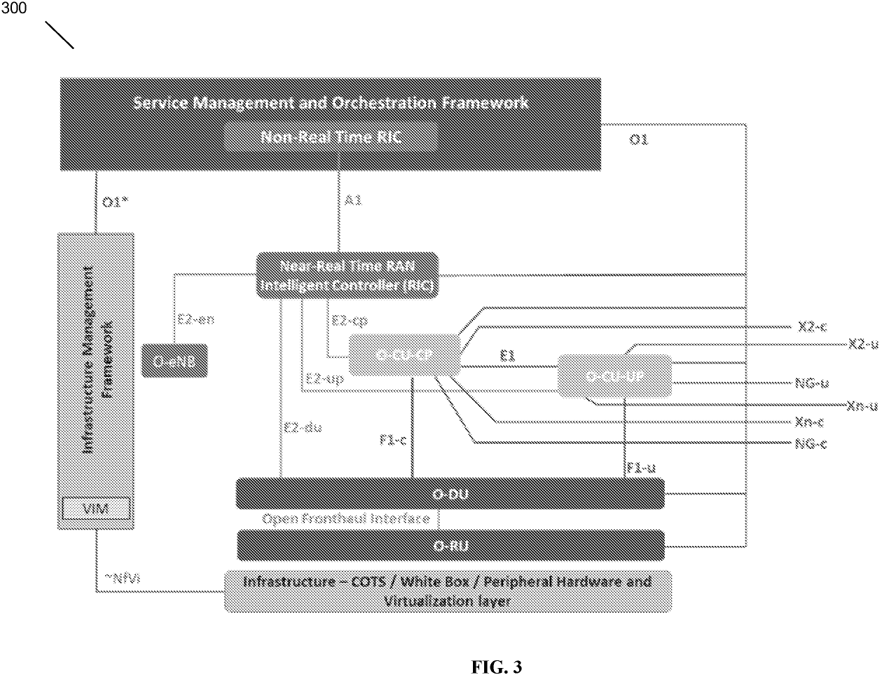

FIG. 3 is a schematic diagram of an Open RAN 4G/5G deployment architecture, in accordance with some embodiments. The O-RAN deployment architecture includes an O-DU and O-RU, as described above with respect to FIG. 1, which together comprise a 5G base station in the diagram as shown. The O-CU-CP (central unit control plane) and O-CU-UP (central unit user plane) are ORAN-aware 5G core network nodes. An ORAN-aware LTE node, O-eNB, is also shown. As well, a near-real time RAN intelligent controller is shown, in communication with the CU-UP, CU-CP, and DU, performing near-real time coordination As well, a non-real time RAN intelligent controller is shown, receiving inputs from throughout the network and specifically from the near-RT RIC and performing service management and orchestration (SMO), in coordination with the operator’s network (not shown).

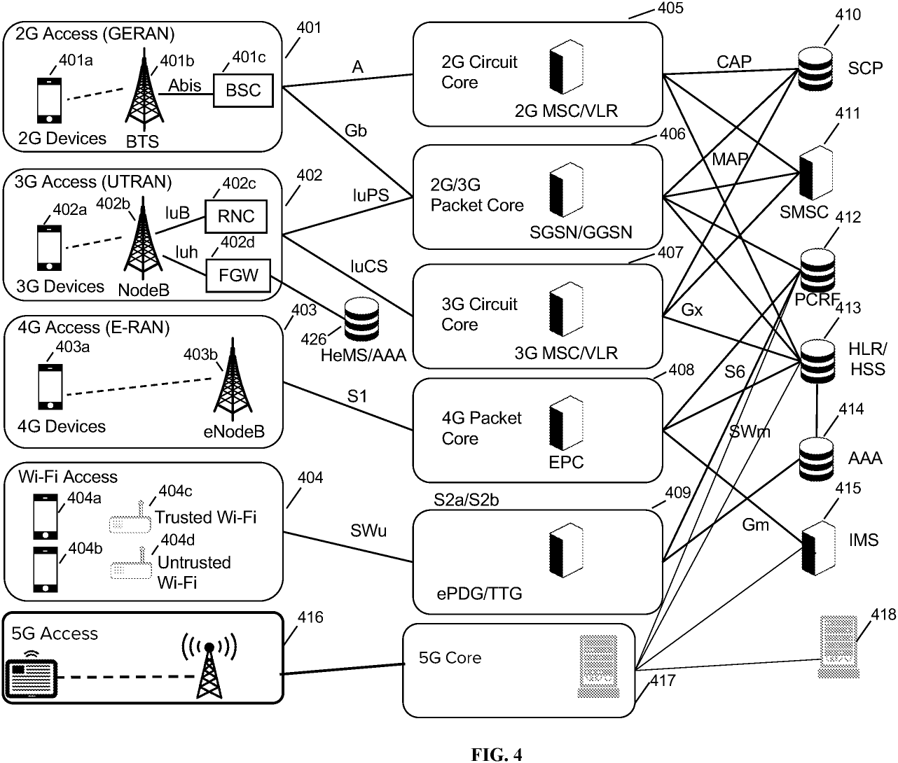

FIG. 4 is a schematic diagram of a multi-RAT core network architecture, in accordance with some embodiments. A schematic network architecture diagram for 3G and other-G prior art networks is shown. The diagram shows a plurality of “Gs,” including 2G, 3G, 4G, 5G and Wi-Fi. 2G is represented by GERAN 401, which includes a 2G device 401a, BTS 401b, and BSC 401c. 3G is represented by UTRAN 402, which includes a 3G UE 402a, nodeB 402b, RNC 402c, and femto gateway (FGW, which in 3GPP namespace is also known as a Home nodeB Gateway or HNBGW) 402d. 4G is represented by EUTRAN or E-RAN 403, which includes an LTE UE 403a and LTE eNodeB 403b. Wi-Fi is represented by Wi-Fi access network 404, which includes a trusted Wi-Fi access point 404c and an untrusted Wi-Fi access point 404d. The Wi-Fi devices 404a and 404b may access either AP 404c or 404d. In the current network architecture, each “G” has a core network. 2G circuit core network 405 includes a 2G MSC/VLR; 2G/3G packet core network 406 includes an SGSN/GGSN (for EDGE or UMTS packet traffic); 3G circuit core 407 includes a 3G MSC/VLR; 4G circuit core 408 includes an evolved packet core (EPC); and in some embodiments the Wi-Fi access network may be connected via an ePDG/TTG using S2a/S2b. Each of these nodes are connected via a number of different protocols and interfaces, as shown, to other, non-“G”-specific network nodes, such as the SCP 430, the SMSC 431, PCRF 432, HLR/HSS 433, Authentication, Authorization, and Accounting server (AAA) 434, and IP Multimedia Subsystem (IMS) 435. An HeMS/AAA 436 is present in some cases for use by the 3G UTRAN. The diagram is used to indicate schematically the basic functions of each network as known to one of skill in the art, and is not intended to be exhaustive. For example, 5G core 417 is shown using a single interface to 5G access 416, although in some cases 5G access can be supported using dual connectivity or via a non-standalone deployment architecture.

Noteworthy is that the RANs 401, 402, 403, 404 and 436 rely on specialized core networks 405, 406, 407, 408, 409, 437 but share essential management databases 430, 431, 432, 433, 434, 435, 438. More specifically, for the 2G GERAN, a BSC 401c is required for Abis compatibility with BTS 401b, while for the 3G UTRAN, an RNC 402c is required for Iub compatibility and an FGW 402d is required for Iuh compatibility. These core network functions are separate because each RAT uses different methods and techniques. On the right side of the diagram are disparate functions that are shared by each of the separate RAT core networks. These shared functions include, e.g., PCRF policy functions, AAA authentication functions, and the like. Letters on the lines indicate well-defined interfaces and protocols for communication between the identified nodes.

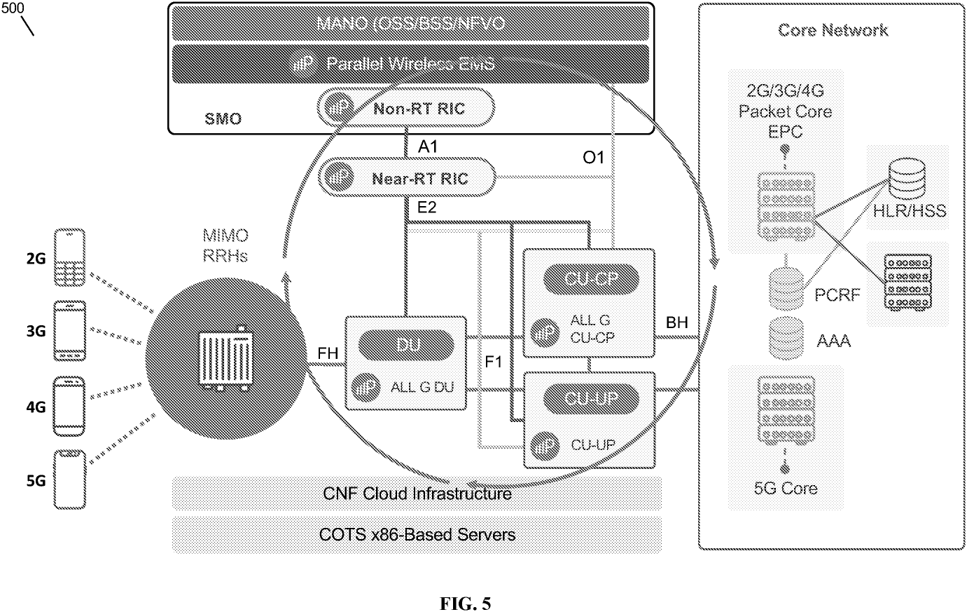

FIG. 5 is a schematic diagram of a multi-RAT RAN deployment architecture, in accordance with some embodiments. Multiple generations of UE are shown, connecting to RRHs that are coupled via fronthaul to an all-G Parallel Wireless DU. The all-G DU is capable of interoperating with an all-G CU-CP and an all-G CU-UP. Backhaul may connect to the operator core network, in some embodiments, which may include a 2G/3G/4G packet core, EPC, HLR/HSS, PCRF, AAA, etc., and/or a 5G core. In some embodiments an all-G near-RT RIC is coupled to the all-G DU and all-G CU-UP and all-G CU-CP. Unlike in the prior art, the near-RT RIC is capable of interoperating with not just 5G but also 2G/3G/4G.

The all-G near-RT RIC may perform processing and network adjustments that are appropriate given the RAT. For example, a 4G/5G near-RT RIC performs network adjustments that are intended to operate in the 100 ms latency window. However, for 2G or 3G, these windows may be extended. As well, the all-G near-RT RIC can perform configuration changes that takes into account different network conditions across multiple RATs. For example, if 4G is becoming crowded or if compute is becoming unavailable, admission control, load shedding, or UE RAT reselection may be performed to redirect 4G voice users to use 2G instead of 4G, thereby maintaining performance for users. As well, the non-RT RIC is also changed to be a near-RT RIC, such that the all-G non-RT RIC is capable of performing network adjustments and configuration changes for individual RATs or across RATs similar to the all-G near-RT RIC. In some embodiments, each RAT can be supported using processes, that may be deployed in threads, containers, virtual machines, etc., and that are dedicated to that specific RAT, and, multiple RATs may be supported by combining them on a single architecture or (physical or virtual) machine. In some embodiments, the interfaces between different RAT processes may be standardized such that different RATs can be coordinated with each other, which may involve interwokring processes or which may involve supporting a subset of available commands for a RAT, in some embodiments.

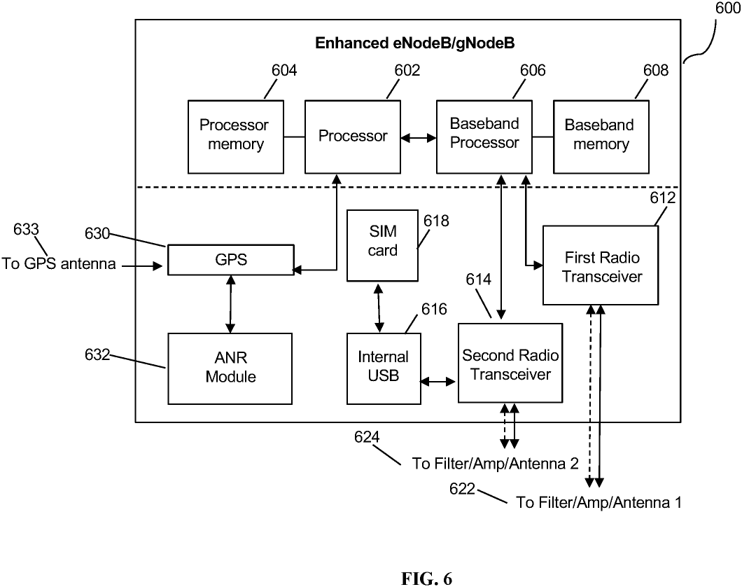

FIG. 6 is an enhanced eNodeB for performing the methods described herein, in accordance with some embodiments. eNodeB 600 may include processor 602, processor memory 604 in communication with the processor, baseband processor 606, and baseband processor memory 608 in communication with the baseband processor. Mesh network node 600 may also include first radio transceiver 612 and second radio transceiver 614, internal universal serial bus (USB) port 616, and subscriber information module card (SIM card) 618 coupled to USB port 616. In some embodiments, the second radio transceiver 614 itself may be coupled to USB port 616, and communications from the baseband processor may be passed through USB port 616. The second radio transceiver may be used for wirelessly backhauling eNodeB 600.

Processor 602 and baseband processor 606 are in communication with one another. Processor 602 may perform routing functions, and may determine if/when a switch in network configuration is needed. Baseband processor 606 may generate and receive radio signals for both radio transceivers 612 and 614, based on instructions from processor 602. In some embodiments, processors 602 and 606 may be on the same physical logic board. In other embodiments, they may be on separate logic boards.

Processor 602 may identify the appropriate network configuration, and may perform routing of packets from one network interface to another accordingly. Processor 602 may use memory 604, in particular to store a routing table to be used for routing packets. Baseband processor 606 may perform operations to generate the radio frequency signals for transmission or retransmission by both transceivers 610 and 612. Baseband processor 606 may also perform operations to decode signals received by transceivers 612 and 614. Baseband processor 606 may use memory 608 to perform these tasks.

The first radio transceiver 612 may be a radio transceiver capable of providing LTE eNodeB functionality, and may be capable of higher power and multi-channel OFDMA. The second radio transceiver 614 may be a radio transceiver capable of providing LTE UE functionality. Both transceivers 612 and 614 may be capable of receiving and transmitting on one or more LTE bands. In some embodiments, either or both of transceivers 612 and 614 may be capable of providing both LTE eNodeB and LTE UE functionality. Transceiver 612 may be coupled to processor 602 via a Peripheral Component Interconnect-Express (PCI-E) bus, and/or via a daughtercard. As transceiver 614 is for providing LTE UE functionality, in effect emulating a user equipment, it may be connected via the same or different PCI-E bus, or by a USB bus, and may also be coupled to SIM card 618. First transceiver 612 may be coupled to first radio frequency (RF) chain (filter, amplifier, antenna) 622, and second transceiver 614 may be coupled to second RF chain (filter, amplifier, antenna) 624.

SIM card 618 may provide information required for authenticating the simulated UE to the evolved packet core (EPC). When no access to an operator EPC is available, a local EPC may be used, or another local EPC on the network may be used. This information may be stored within the SIM card, and may include one or more of an international mobile equipment identity (IMEI), international mobile subscriber identity (IMSI), or other parameter needed to identify a UE. Special parameters may also be stored in the SIM card or provided by the processor during processing to identify to a target eNodeB that device 600 is not an ordinary UE but instead is a special UE for providing backhaul to device 600.

Wired backhaul or wireless backhaul may be used. Wired backhaul may be an Ethernet-based backhaul (including Gigabit Ethernet), or a fiber-optic backhaul connection, or a cable-based backhaul connection, in some embodiments. Additionally, wireless backhaul may be provided in addition to wireless transceivers 612 and 614, which may be Wi-Fi 802.11a/b/g/n/ac/ad/ah, Bluetooth, ZigBee, microwave (including line-of-sight microwave), or another wireless backhaul connection. Any of the wired and wireless connections described herein may be used flexibly for either access (providing a network connection to UEs) or backhaul (providing a mesh link or providing a link to a gateway or core network), according to identified network conditions and needs, and may be under the control of processor 602 for reconfiguration.

A GPS module 630 may also be included, and may be in communication with a GPS antenna 632 for providing GPS coordinates, as described herein. When mounted in a vehicle, the GPS antenna may be located on the exterior of the vehicle pointing upward, for receiving signals from overhead without being blocked by the bulk of the vehicle or the skin of the vehicle. Automatic neighbor relations (ANR) module 632 may also be present and may run on processor 602 or on another processor, or may be located within another device, according to the methods and procedures described herein.

Other elements and/or modules may also be included, such as a home eNodeB, a local gateway (LGW), a self-organizing network (SON) module, or another module. Additional radio amplifiers, radio transceivers and/or wired network connections may also be included.

In any of the scenarios described herein, where processing may be performed at the cell, the processing may also be performed in a cloud, at a cloud coordination server, in a virtualized BBU or vBBU, in a cloud RAN, in a cloud portion of a functional split architecture, or in coordination with a cloud coordination server. A mesh node may be an eNodeB. An eNodeB may be in communication with the cloud coordination server via an X2 protocol connection, or another connection. The eNodeB may perform inter-cell coordination via the cloud communication server when other cells are in communication with the cloud coordination server. The eNodeB may communicate with the cloud coordination server to determine whether the UE has the ability to support a handover to Wi-Fi, e.g., in a heterogeneous network.

Although the methods above are described as separate embodiments, one of skill in the art would understand that it would be possible and desirable to combine several of the above methods into a single embodiment, or to combine disparate methods into a single embodiment. For example, all of the above methods could be combined. In the scenarios where multiple embodiments are described, the methods could be combined in sequential order, or in various orders, as necessary.

Although the above systems and methods for providing interference mitigation are described in reference to the Long Term Evolution (LTE) standard, one of skill in the art would understand that these systems and methods could be adapted for use with other wireless standards or versions thereof. The inventors have understood and appreciated that the present disclosure could be used in conjunction with various network architectures and technologies. Wherever a 4G technology is described, the inventors have understood that other RATs have similar equivalents, such as a gNodeB for 5G equivalent of eNB. Wherever an MME is described, the MME could be a 3G RNC or a 5G AMF/SMF. Additionally, wherever an MME is described, any other node in the core network could be managed in much the same way or in an equivalent or analogous way, for example, multiple connections to 4G EPC PGWs or SGWs, or any other node for any other RAT, could be periodically evaluated for health and otherwise monitored, and the other aspects of the present disclosure could be made to apply, in a way that would be understood by one having skill in the art.

Additionally, the inventors have understood and appreciated that it is advantageous to perform certain functions at a coordination server, such as the Parallel Wireless HetNet Gateway, which performs virtualization of the RAN towards the core and vice versa, so that the core functions may be statefully proxied through the coordination server to enable the RAN to have reduced complexity. Therefore, at least four scenarios are described: (1) the selection of an MME or core node at the base station; (2) the selection of an MME or core node at a coordinating server such as a virtual radio network controller gateway (VRNCGW); (3) the selection of an MME or core node at the base station that is connected to a 5G-capable core network (either a 5G core network in a 5G standalone configuration, or a 4G core network in 5G non-standalone configuration); (4) the selection of an MME or core node at a coordinating server that is connected to a 5G-capable core network (either 5G SA or NSA). In some embodiments, the core network RAT is obscured or virtualized towards the RAN such that the coordination server and not the base station is performing the functions described herein, e.g., the health management functions, to ensure that the RAN is always connected to an appropriate core network node. Different protocols other than SlAP, or the same protocol, could be used, in some embodiments.

In some embodiments, the base stations described herein may support Wi-Fi air interfaces, which may include one or more of IEEE 802.11a/b/g/n/ac/af/p/h. In some embodiments, the base stations described herein may support IEEE 802.16 (WiMAX), to LTE transmissions in unlicensed frequency bands (e.g., LTE-U, Licensed Access or LA-LTE), to LTE transmissions using dynamic spectrum access (DSA), to radio transceivers for ZigBee, Bluetooth, or other radio frequency protocols, or other air interfaces.

In some embodiments, the software needed for implementing the methods and procedures described herein may be implemented in a high level procedural or an object-oriented language such as C, C++, C#, Python, Java, or Perl. The software may also be implemented in assembly language if desired. Packet processing implemented in a network device can include any processing determined by the context. For example, packet processing may involve high-level data link control (HDLC) framing, header compression, and/or encryption. In some embodiments, software that, when executed, causes a device to perform the methods described herein may be stored on a computer-readable medium such as read-only memory (ROM), programmable-read-only memory (PROM), electrically erasable programmable-read-only memory (EEPROM), flash memory, or a magnetic disk that is readable by a general or special purpose-processing unit to perform the processes described in this document. The processors can include any microprocessor (single or multiple core), system on chip (SoC), microcontroller, digital signal processor (DSP), graphics processing unit (GPU), or any other integrated circuit capable of processing instructions such as an x86 microprocessor.

In some embodiments, the radio transceivers described herein may be base stations compatible with a Long Term Evolution (LTE) radio transmission protocol or air interface. The LTE-compatible base stations may be eNodeBs. In addition to supporting the LTE protocol, the base stations may also support other air interfaces, such as UMTS/HSPA, CDMA/CDMA2000, GSM/EDGE, GPRS, EVDO, 2G, 3G, 5G, TDD, or other air interfaces used for mobile telephony.

The system may include 5G equipment. 5G networks are digital cellular networks, in which the service area covered by providers is divided into a collection of small geographical areas called cells. Analog signals representing sounds and images are digitized in the phone, converted by an analog to digital converter and transmitted as a stream of bits. All the 5G wireless devices in a cell communicate by radio waves with a local antenna array and low power automated transceiver (transmitter and receiver) in the cell, over frequency channels assigned by the transceiver from a common pool of frequencies, which are reused in geographically separated cells. The local antennas are connected with the telephone network and the Internet by a high bandwidth optical fiber or wireless backhaul connection.

5G uses millimeter waves which have shorter range than microwaves, therefore the cells are limited to smaller size. Millimeter wave antennas are smaller than the large antennas used in previous cellular networks. They are only a few inches (several centimeters) long. Another technique used for increasing the data rate is massive MIMO (multiple-input multiple-output). Each cell will have multiple antennas communicating with the wireless device, received by multiple antennas in the device, thus multiple bitstreams of data will be transmitted simultaneously, in parallel. In a technique called beamforming the base station computer will continuously calculate the best route for radio waves to reach each wireless device, and will organize multiple antennas to work together as phased arrays to create beams of millimeter waves to reach the device.

In some embodiments, the base stations described herein may support Wi-Fi air interfaces, which may include one or more of IEEE 802.11a/b/g/n/ac/af/p/h. In some embodiments, the base stations described herein may support IEEE 802.16 (WiMAX), to LTE transmissions in unlicensed frequency bands (e.g., LTE-U, Licensed Access or LA-LTE), to LTE transmissions using dynamic spectrum access (DSA), to radio transceivers for ZigBee, Bluetooth, or other radio frequency protocols, or other air interfaces.

The foregoing discussion discloses and describes merely exemplary embodiments of the present invention. In some embodiments, software that, when executed, causes a device to perform the methods described herein may be stored on a computer-readable medium such as a computer memory storage device, a hard disk, a flash drive, an optical disc, or the like. As will be understood by those skilled in the art, the present invention may be embodied in other specific forms without departing from the spirit or essential characteristics thereof. For example, wireless network topology can also apply to wired networks, optical networks, and the like. The methods may apply to LTE-compatible networks, to UMTS-compatible networks, or to networks for additional protocols that utilize radio frequency data transmission. Various components in the devices described herein may be added, removed, split across different devices, combined onto a single device, or substituted with those having the same or similar functionality.

Although the present disclosure has been described and illustrated in the foregoing example embodiments, it is understood that the present disclosure has been made only by way of example, and that numerous changes in the details of implementation of the disclosure may be made without departing from the spirit and scope of the disclosure, which is limited only by the Asserts which follow. Various components in the devices described herein may be added, removed, or substituted with those having the same or similar functionality. Various steps as described in the figures and specification may be added or removed from the processes described herein, and the steps described may be performed in an alternative order, consistent with the spirit of the invention. Features of one embodiment may be used in another embodiment.

1. A method for providing communication Forward Error Correction (FEC) optimization for virtualized platforms, comprising:
calculating a cut off time used to terminate total FEC processing duration;
processing code blocks received in a subframe in an order defined by a sorting stage; and
wherein processing code blocks comprises:
checking if a current time has exceeded the cut off time cut off value;
when the current time has exceeded the cut off time value, then setting a Cyclic
Redundancy Code (CRC) FAIL and moving onto a next code block without decoding;
when the current time has not exceeded the cut off time value, then running a single iteration of decoding and checking a code block CRC;
when the code block CRC is PASS then decoding is successful and moving onto a next code block;
when the code block CRC is FAIL then checking if a maximum number of FEC iterations has been reached;
when maximum number of FEC iterations has not been reached repeating the steps of calculating and processing code blocks; and
when maximum number of FEC iterations has been reached then moving onto the next code block.
